(19) United States
(12) Patent Application Publication
(10) Pub. No.: US 2024/0413119 A1
(43) Pub. Date: Dec. 12, 2024

(54) CONTACT ASSEMBLY FOR POWER SEMICONDUCTOR CHIPS AND POWER ELECTRONICS MODULE

(71) Applicant: ZF Friedrichshafen AG, Friedrichshafen (DE)

(72) Inventors: Fabian Hohmann, Hofbieber (DE); Stefan Hain, Speichersdorf (DE)

(73) Assignee: ZF Friedrichshafen AG, Friedrichshafen (DE)

(21) Appl. No.: 18/735,581

(22) Filed: Jun. 6, 2024

(30) Foreign Application Priority Data
Jun. 7, 2023 (DE) 10 2023 205 330.6

(51) Int. Cl. H01L 23/00; H01L 25/11; H02K 11/00

(52) U.S. Cl. CPC H01L 24/32; H01L 24/29; H01L 25/115; H02K 11/0094; H01L 2224/29147; H01L 2224/32225

(57) ABSTRACT

A contact assembly for power semiconductor chips has a substrate, at least two power semiconductor chips with a first terminal on the substrate such that they are electrically connected, and at least one contact region facing outward from the substrate, with the same type of terminal for connecting to the power semiconductor, a contact component in the form of a conductive metal film, which is at least partially coated with an insulating layer, which has holes exposing the metal film for terminals for the power semiconductor chips, and wherein at least part of the metal film protrudes from the insulating layer and is connected to a dedicated contact region on the substrate in order to connect to identical types of terminals for the power semiconductor chips.

### CROSS-REFERENCE TO RELATED APPLICATION

This application claims priority to German Application No. 10 2023 205 330.6, filed on Jun. 7, 2023, the entirety of which is hereby fully incorporated by reference herein.

### FIELD

The present disclosure relates to the field of electric mobility, in particular power electronics modules for an electric drive and the electric contact to the power semiconductor chips.

### BACKGROUND

The use of electronics modules in motor vehicles, specifically power electronics modules, has increased substantially over the last few decades. This is due partly to the need to improve fuel consumption and vehicle performance, and partly to the advances in semiconductor technology. The main component of such an electronics module is the DC/AC inverter which supplies machines such as electric motors and generators with a multiphase alternating current (AC). These inverters convert direct current (DC) generated by a DC power source such as a battery into a multiphase alternating current (AC). Inverters have numerous electronic components for this, e.g. power semiconductor chips, with which bridge circuits (such as half bridges) are created.

There are already standardized electronics modules, normally made of two MOSFET chips (power semiconductor chips), the drains of which are attached to a printed circuit board (PCB) or substrate (DCB) with a sinter layer. These modules are called DDP modules (Discrete Dual Package modules). The source terminals for both chips are connected to copper tabs protruding from the printed circuit board (PCB) or substrate (DCB) by a copper clip or wires to obtain a current from the electronics module. Neither of these connections results in an optimal low inductive connection to the power semiconductors in the chips. A higher commutation inductivity increases the voltage drop at the chip. The fact that this additional voltage drop cannot be measured from outside the chip is another reason to keep this inductivity low.

### SUMMARY

A fundamental object of the present disclosure is to therefore create an improved connection for transferring power from the power semiconductor chips to outside the power semiconductor module.

This problem is solved by the features disclosed herein. Advantageous embodiments are also the subject matter of the present disclosure.

A contact assembly for power semiconductor chips is proposed, which has a substrate, at least two power semiconductor chips with a first terminal on the substrate, such that they are electrically connected, and at least one contact facing outward that has the same type of terminals as the power semiconductor chips for obtaining an electrical connection, and a contact component made of an electrically conductive metal film, at least part of which has an insulating layer, which has a hole in it exposing the metal film, to which a terminal for each of the power semiconductor chips can be connected, with at least part of the metal film extending from the insulating layer and in contact with a dedicated contact region on the substrate in order to obtain an electrical connection to the identical terminals for the power semiconductor chips.

In one embodiment, the power semiconductor chips are MOSFETs, and the first terminal is connected to a drain on the MOSFET, while the metal film forms a source region, and a source terminal for the power semiconductor chip is connected to a dedicated hole for the metal film, and the contact region forms a source contact that is connected to the part of the metal film protruding from the insulating layer.

In one embodiment, the contact assembly also has two more contact regions facing out of the substrate that form a gate contact and a Kelvin source contact, and the metal film is subdivided by at least one insulating layer to form a gate contact and a Kelvin source contact for each of the power semiconductor chips, each section having a hole in the insulating layer, such that the dedicated terminal on the dedicated power semiconductor chip is connected to each hole, and in each case, another part of the metal film protrudes from the insulating layer, one of which forms a gate contact and the other a Kelvin source contact, which are in contact with the dedicated contact region on the substrate.

In one embodiment, the gate regions and Kelvin source regions are at opposite ends of the power semiconductor chips, and the electrical connection is obtained with the dedicated contact region by connections insulated from one another in the x, y, or z direction.

The metal film is made of copper in one embodiment.

The metal film has an insulating layer on both sides in one embodiment.

A power electronics module is also obtained that has at least one topological switch containing at least two parallel power semiconductor chips (10), to which contact is obtained by the contact assembly (100) according to any of the preceding claims.

A power electronics assembly for operating a three-phase electric motor in a vehicle is also obtained, containing the power electronics module, and at least one ECU (computer), which is connected to the electric motor such that it can control and regulate it, and to the power electronics module. The ECU can be part of the power electronics module, or separate therefrom.

An electric drive for a motor vehicle is also obtained, which has a three-phase electric motor and a battery, as well as the power electronics assembly connected thereto.

A motor vehicle is also obtained, which has the electric drive in the form of an electric axle drive.

Other features and advantages of the present disclosure can be derived from the following description of exemplary embodiments of in reference to the drawings showing details of the present disclosure, and the claims. The individual features can be realized in and of themselves or in various arbitrary combinations to obtain different variations of the present disclosure.

Preferred embodiments shall be explained below in greater detail in reference to the drawings.

### BRIEF DESCRIPTION OF THE DRAWINGS

FIG. 1 shows a fundamental structure for a DDP module according to the prior art.

FIG. 2 shows a fundamental structure for a contact component according to one embodiment of the present disclosure.

FIG. 3 shows a fundamental structure for a contact component according to another embodiment of the present disclosure.

FIG. 4 shows a fundamental structure for a contact component with two metal films placed one on top of the other, according to another embodiment of the present disclosure.

### DETAILED DESCRIPTION

Identical elements and functions have the same reference symbols in the following descriptions of the drawings.

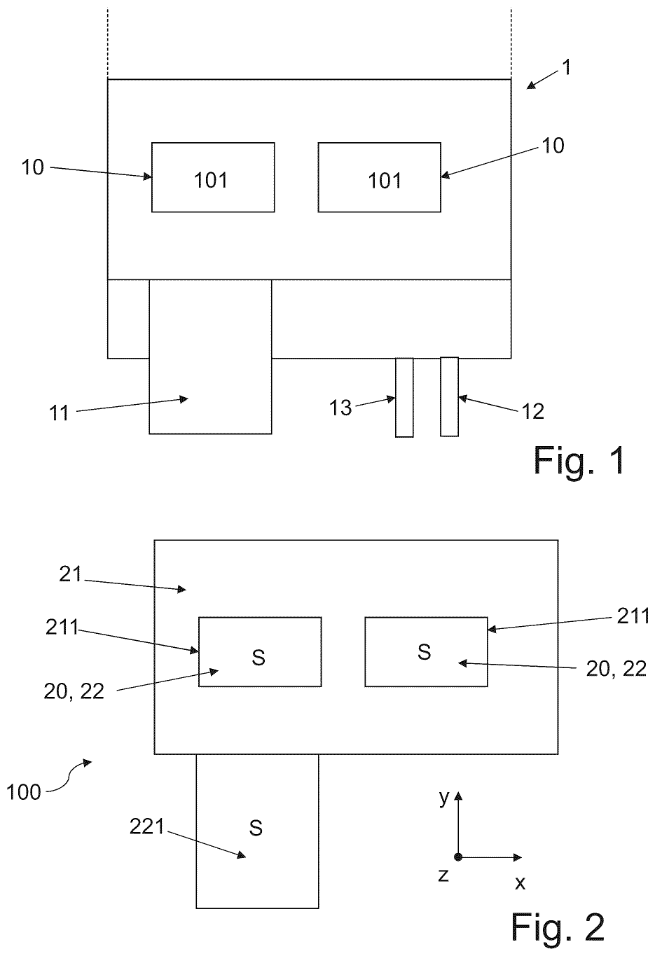

As mentioned above, power has been transferred in current DDP modules between the power semiconductor chips 10, e.g. MOSFETs, on a printed circuit board (PCB) or substrate (DCB) 1 in a power electronics module so far, in that the terminals for the power semiconductor chips 10 that are not in direct contact with the printed circuit board or substrate (DCB) are connected to a dedicated contact region 11-13 on the printed circuit board or substrate (DCB) by a copper clip or connecting wire. This would be the connections of the terminals 101 on the power semiconductor chips 10 to the contact region 11 in FIG. 1. When MOSFETs are used as the power semiconductor chips 10, the terminal 101 is a source terminal, and the contact region 11 is a source contact region 11.

The contact assembly 100 described below is proposed to obtain a better low inductive connection to the power semiconductor in the power semiconductor chip 10. This contains a substrate 1, power semiconductor chips 10, and a contact component 20 with which a surface connection and electric contact to the power semiconductor chips 10 can be obtained.

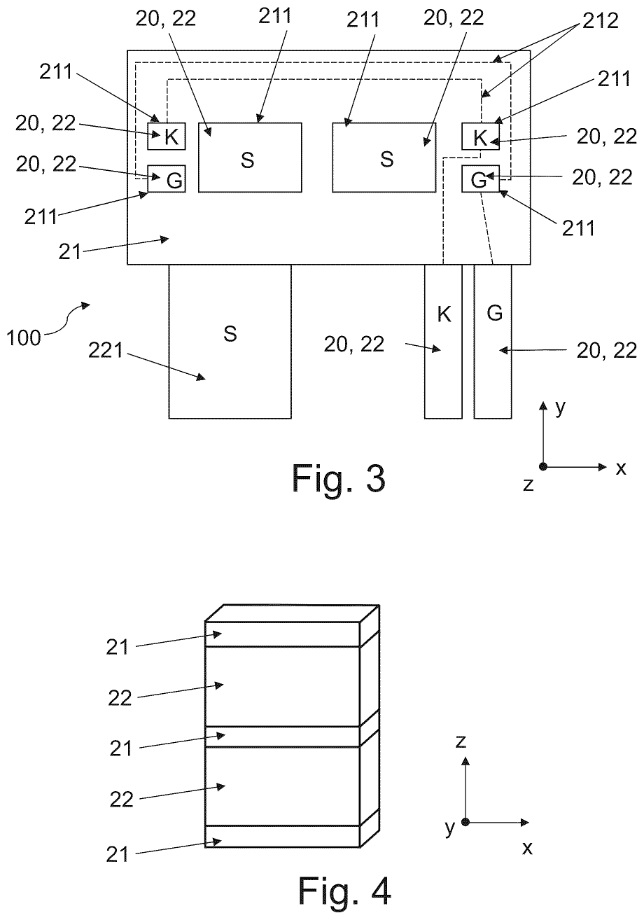

One embodiment of the contact assembly 100 is shown in FIG. 2. An alternative embodiment is shown in FIG. 3.

The contact component 20 is made of an electrically conductive metal film 22. This metal film 22 can be shaped along the z-axis, in particular through deep drawing. Ideally, its maximum thickness (along the z-axis) is 1 mm. At least part of it has an insulating layer 21. There are holes 211 in the insulating layer 21 that expose the metal film 22 for obtaining contact to the power semiconductor chips 10. The holes 211 therefore expose the metal forming the metal film 22. The holes 211 allow a terminal 101 to connect to a power semiconductor chip 10 when the contact component 20 is placed on the substrate 1. The holes 211 are ideally the same size as the terminals 101 for the power semiconductor chips 10, to obtain a reliable contact. The contact can be obtained with soldering or sintering.

A part 221 of the metal film 22 also protrudes from the insulating layer 21 to obtain contact with the contact region 11-13 of the substrate 1 outside the power electronics module, e.g. to a negative DC contact or a drain contact on another power semiconductor.

The metal film 22 is preferably made of copper. Its size is adjusted to the ampacity of the power semiconductor chips 10 and the number of power semiconductor chips 10. The surface area of the substrate 1 covered by the metal film 22 depends on the structure of the substrate 1. The size and orientation of the insulated part of the metal film 22 are dependent on the size and position of the power semiconductor chips 10 on the substrate 1. The metal film 22 provides connecting surfaces for the terminals 101 of the two power semiconductors 10 and the power source contact (hole 211). Depending on the embodiment, there are also contact surfaces for the subsidiary source (Kelvin source) and the gate contact. The goal is to obtain a reliable contact to the terminal 101 for the power semiconductor chip 10. The insulating layer 21 could also merely form a frame around the holes 211, such that it is only slightly larger than the surface covered by the power semiconductor chips 10. In this manner, it reaches to the outer part of the power semiconductor chips 10 where the inverse voltage declines. This simplifies the positioning, because it provides greater tolerances.

The following embodiments are described based on MOSFETs that have drain, source, gate, and signal (Kelvin source) terminals forming the power semiconductors in the power semiconductor chips 10 that are to be connected to. Other power semiconductors could also be used that have the appropriate terminals, e.g. an IGBT, for which the terminals must be selected accordingly (MOSFET: gate, drain, source; IGBT: gate, collector, emitter).

As explained in the introduction, the drain for the MOSFET on one side of the power semiconductor chip 10 (which therefore is not visible in the drawings) is connected directly to the substrate 1 (to obtain an electric and mechanical contact). The source terminal is on the other side of the power semiconductor chip 10, indicated in FIG. 1 as the terminal 101. The substrate 1 also has another source contact region 11, a gate contact region 12, and a signal contact region (Kelvin source contact) 13, with which the connection to outside the substrate 1 (for the power electronics module) is obtained. The contact region 11 is connected to the dedicated terminals (only terminal 101 is shown in the drawings). Instead of copper clips or wires, this is obtained with the contact component 20 of the present disclosure. The contact regions 12 and 13 can be connected in the same manner as the other contact region 11, or with wires, as in the prior art.

FIG. 2 shows an embodiment of the contact component 20 in which the holes 211 and the part 221 of the metal film 22 protruding from the insulating layer 21 are intended for a power source connection, thus serving as the source region S. the holes 211 are placed on the terminals 101 shown in FIG. 1 for the power semiconductor chips 10 on the substrate 1, and thus connected thereto (electrically and mechanically). The part 221 protruding from the metal film 22 is connected to the contact region 11 on the substrate 1 (electrically and mechanically), which thus forms the power source contact region 11 for the power semiconductor module. In this manner, an electrically conductive connection is obtained between these components by the holes 211 and the part 221 of the metal film 22 protruding from the metal film 22.

Another embodiment is shown in FIG. 3, in which not only a power source connection is obtained, but also a connection to the gate and Kelvin sources. Two more parts of the metal film 22 are provided for this, which serve as the gate region G and the Kelvin source region K, which is electrically insulated therefrom by then insulating layer 21. The insulating layer 21 also has holes 211 for these regions G, K.

It should be noted that the metal film 22 can be subdivided into multiple parts (on top of one another along the z-axis, or adjacent to one another along the x and y axes), with insulation between the individual parts, in order to separate the regions S, G, and K from one another.

The gate and Kelvin source regions G, K on each power semiconductor chip 10 are at regions on the power semiconductor chips 10 specially provided for this (they assume the source region S in its middle in FIG. 3), as can be seen in FIG. 3. The gate and Kelvin source contact regions 12, 13 on the substrate 1 are located next to the source contact region 11. This position cannot be connected to all of the gate and signal contact regions 12, 13, because this would result in a conflict with the source contact. For this reason, it is proposed to obtain the connection with holes 212 in the insulating layer 21 on the part of the metal film 22 lying opposite of the part 221 of the metal film 22 protruding from the substrate 1, as indicated in FIG. 3 by the broken lines.

In another embodiment, shown in FIG. 4 (shown by way of example for the gate region G and the Kelvin source region K), the contact component 20 can also be formed by two (or more) metal films 22 placed one on top of the other, which are separated from one another by an insulating layer 21. This allows for numerous signals to be transferred at different levels. This is particularly advantageous with regard to the connections for the gate region G and the signal region (Kelvin source K), for obtaining the lowest possible inductivity.

The present disclosure has been described for two power semiconductor chips 10. The person skilled in the art could also integrate more than two power semiconductor chips 10 without difficulty.

A very low inductivity can be obtained in control and performance circuits with the film technology proposed here (metal film 22).

The power electronics module in the framework of this disclosure is used for operating an electric drive in a battery-powered motor vehicle. The motor vehicle in this case is a utility vehicle such as a truck or bus, or a passenger automobile. The power electronics module contains a DC/AC inverter, formed by numerous topological switches, which in turn are formed by numerous power semiconductor chips 10. It can also contain an AC/DC rectifier, a DC/DC converter, a transformer, and/or other electrical converters, or part of such a converter, or it can be a part thereof. In particular, the power electronics module is used to power an electric machine, e.g. an electric motor and/or generator. A DC/AC inverter is preferably used to generate a multiphase alternating current from a direct current generated by a power source such as a battery with a DC voltage.

DC/DC converters and inverters 1 for electric drives in motor vehicles, in particular passenger automobiles and utility vehicles such as busses are configured for high voltage and are configured in particular for an inverse voltage class starting at ca. 650 volts.

The inverter assembly described herein can be used for example in motor vehicles. The motor vehicle can contain an axle powered with electricity from the electric drive, in particular.

### LIST OF REFERENCE SYMBOLS

100 contact assembly
1 substrate, e.g. DBC
10 power semiconductor chip
101 terminal for 10
11 source contact region for 1
12 gate contact region for 1
13 signal contact region (Kelvin source contact) for 1
20 contact component
21 insulating layer
211 hole
22 metal film
221 part of the metal film
S source region
G gate region
K Kelvin source region

1. A contact assembly for power semiconductor chips, comprising:
a substrate;
at least two power semiconductor chips, each with a first terminal on the substrate such that they are configured to be electrically connected thereto;
at least one contact region facing outward from the substrate and configured for connecting to second terminals of each of the at least two power semiconductors; and
a contact component comprising a conductive metal film that is at least partially coated with an insulating layer comprising holes exposing the metal film to the second terminals of the at least two power semiconductor chips,
wherein at least part of the metal film protrudes from the insulating layer and is connected to a dedicated contact region on the substrate in order to connect to the second terminals of the power semiconductor chips.

2. The contact assembly according to claim 1, wherein
the power semiconductor chips are MOSFETs, and the first terminals are connected to a drain for the MOSFETS,
the metal film forms a source region and connects the second terminals as source terminals of the power semiconductor chips to a dedicated area on the metal film within a dedicated hole in the insulating layer on the metal film, and
the contact region forms a source contact region that is connected to the part of the metal film that protrudes from the insulating layer.

3. The contact assembly according to claim 2, comprising:
at least two more contact regions that face outward from the substrate, which form a gate contact region and a Kelvin source contact region,
wherein the metal film is subdivided into other regions by the insulating layer or at least one other insulating layer, wherein the other regions form a gate region and a Kelvin source region for each power semiconductor chip, and wherein a hole for each region exists in the insulating layer or the at least one other insulating layer, and
wherein each one of the other regions is connected to a corresponding terminal of the power semiconductor chips within each respective hole, and
wherein at least two other parts of the metal film also protrude from the insulating layer in each case, one of which forms a gate contact, and the other of which forms a Kelvin source contact, which are connected to the at least two more contact regions of the substrate.

4. The contact assembly according to claim 3,
wherein the gate region and Kelvin source region are at opposite ends of the power semiconductor chips, and
wherein electric contact to the at least two more contact regions is obtained with connections that are insulated from one another in x, y, or z directions.

5. The contact assembly according to claim 1, wherein the metal film is made of copper.

6. The contact assembly according to claim 1, wherein the metal film comprises the insulating layer on both sides.

7. A power electronics module comprising:
at least one topological switch comprising the at least two power semiconductor chips in parallel, which are connected by the contact assembly according to claim 1.

8. A power electronics assembly for operating a three-phase electric motor in a
vehicle, wherein the power electronics assembly comprises:
the power electronics module according to claim 7; and
at least one ECU that is connected to the electric motor and to the power electronics module, and configured to control and regulate the electric motor.

9. An electric drive for a motor vehicle, comprising:
a three-phase electric motor;
a battery; and
the power electronics assembly according to claim 8, which is connected to the three-phase electric motor and the battery.

10. A motor vehicle comprising:
the electric drive according to claim 9, which forms an electric axle drive.
